(19) United States
(12) Patent Application Publication
(10) Pub. No.: US 2015/0101853 A1
(43) Pub. Date: Apr. 16, 2015

(54) TOUCH SENSOR

(71) Applicant: SAMSUNG ELECTRO-MECHANICS CO., LTD., Gyeonggi-Do (KR)

(72) Inventors: Tae Kyung LEE, Gyeonggi-Do (KR); Beom Seok OH, Gyeonggi-Do (KR); Kee Su JEON, Gyeonggi-Do (KR); Man Sub SHIN, Gyeonggi-Do (KR)

(73) Assignee: SAMSUNG ELECTRO-MECHANICS CO., LTD., Gyeonggi-Do (KR)

(21) Appl. No.: 14/514,020

(22) Filed: Oct. 14, 2014

(30) Foreign Application Priority Data
Oct. 14, 2013 (KR) 10-2013-0122125
Mar. 26, 2014 (KR) 10-2014-0035516

(51) Int. Cl. H05K 1/02; H05K 1/03

(52) U.S. Cl. CPC H05K 1/02; H05K 1/0313; H05K 1/0274; H05K 2201/10151; H05K 2201/10121
USPC 174/258; 428/194; 174/268

(57) ABSTRACT

Embodiments of the invention provide a touch sensor including a window substrate and a bezel layer formed on outer edges of one surface of the window substrate, wherein the bezel layer includes a printed layer formed on the window substrate, a medium layer formed on the printed layer and having a refractive index lower than that of the printed layer, and a reflective layer formed on the medium layer. According to at least one embodiment, the bezel layer formed on the window substrate is reduced in thickness and various colors are more easily implemented.

### CROSS REFERENCE TO RELATED APPLICATION

This application claims the benefit of and priority under 35 U.S.C. §119 to Korean Patent Application No. KR 10-2013-0122125, entitled “TOUCH SENSOR,” filed on Oct. 14, 2013, and Korean Patent Application No. KR 10-2014-0035516, entitled “TOUCH SENSOR” filed on Mar. 26, 2014, which are hereby incorporated by reference in their entirety into this application.

### BACKGROUND

1. Field of the Invention

The present invention relates to a touch sensor.

2. Description of the Related Art

Due to the development of computers using digital technologies, auxiliary equipment of computers has also been developed, and personal computers, portable transmission devices, and other personalized information processing devices perform text and graphic processing by using, various input devices, such as a keyboard or a mouse.

However, the rapid increase of an information-oriented society has extended the purpose of computers, such that a currently used keyboard and mouse serving as input devices are insufficient to effectively drive products. Thus, demand for a device allowing any one to easily input information, as well as being simple and reducing the possibility of erroneous manipulation, is increasing.

In addition, interest in techniques regarding an input device, beyond a level satisifying general functions, has been shifted to, for example, high reliability, durability, innovativeness, designing, processing-related technique, and in order to achieve such objects, a touch sensor allowing for inputting information, such as text or graphics, for example, has been developed as an input device.

A touch sensor is a tool installed on a display screen of a flat panel display device such as an electronic notebook, a liquid crystal display (LCD) device, a plasma display panel (PDP), an electroluminescence (EL), as non-limiting examples, and an image display device, such as a cathode ray tube (CRT), as a non-limiting example, to allow users to select desired information while viewing the image display device.

Touch sensors are classified as a resistive-type touch sensor, a capacitive-type touch sensor, an electromagnetic-type touch sensor, a surface acoustic wave (SAW)-type touch sensor, and an infrared-type touch sensor. Various types of touch sensor arc employed in electronic products in consideration of signal amplification, difference in resolution, difficulty in designing and processing techniques, optical properties, electrical properties, mechanical properties, environment-resistant characteristics, input characteristics, durability, and economical efficiency, and currently, resistive-type touch sensors and capacitive-type touch sensors are widely used in extensive fields.

For example, a touch sensor may be configured to have a structure in which a transparent substrate and a sensing unit are bonded by the medium of an adhesive, or may be formed such that a bezel part formed on the edges of the transparent substrate covers a bus line of the sensing unit as in the related art document mentioned below.

Recently, importance of design of the exterior of IT devices has been increased and display screens are also increased in size. In particular, efforts have been made to reduce a thickness of a bezel part to increase a display screen and implement full color close to the original, without increasing a size of the exterior of devices, as well as a bezel employing a simple black color, as described, for example, in Korean Patent Publication No. 2011-0053940.

However, an area and a thickness of a bezel part may vary depending on a color of a bezel part desired to be implemented, and in particular, in case of a color having a bright tone allowing light to be easily transmitted therethrough, like white, a thickness of a bezel part is inevitably increased to minimize light transmittance, which runs counter to the trend of IT devices whose size and thickness are decreased.

### SUMMARY

Accordingly, embodiments of the invention have been made to provide a touch sensor in which a bezel layer of a window substrate is reduced in thickness, various colors are easily implemented, operation reliability and operational performance are enhanced.

According to an embodiment of the invention, there is provided a touch sensor including a window substrate, and a bezel layer formed on outer edges of one surfaces of the window substrate, wherein the bezel layer includes a printed layer formed on the window substrate, a medium layer formed on the printed layer and having a refractive index lower than that of the printed layer, and a reflective layer formed on the medium layer.

According to at least one embodiment, the touch sensor further includes a black printed layer formed on the reflective layer.

According to at least one embodiment, the black printed layer is formed of a carbon-based material (graphene oxide, diamond line carbon (DLC)), a chromium-based oxide (CrO or CrO₂), a copper-based oxide (CuO), a manganese-based oxide (MnO₂), a cobalt-based oxide (CoO), a sulfide (CoS₂, Co₃S₄), a nickel-based oxide (Ni₂O₃), or any combination thereof.

According to at least one embodiment, the touch sensor further includes an electrode pattern formed within the bezel layer, an insulating layer formed on the reflective layer of the bezel layer, and an electrode wiring connected to one end of the electrode pattern and formed on the insulating layer to form electrical connection.

According to at least one embodiment, the printed layer includes a material having a refractive index ranging from 1.3 to 2.7 in a wavelength range of visible light.

According to at least one embodiment, the medium layer includes a material having a refractive index ranging from 1 to 2.7 in a wavelength range of visible light.

According to at least one embodiment, the medium layer is formed of an optical clear adhesive (OCA).

According to at least one embodiment, the reflective layer is formed as a metal layer and reflectivity of the metal layer is equal to or greater than 0.8.

According to at least one embodiment, the reflective layer is formed as a metal layer and specific resistance (ρ) of the metal layer is equal to or smaller than 10 at a temperature of 20° C.

According to at least one embodiment, a thickness of the bezel layer in a stacking direction is equal to or smaller than 10 μm.

According to at least one embodiment, the printed layer is formed of titanium dioxide (TiO₂), an aluminum oxide (Al₂O₃), a silicon dioxide (SiO₂), a hafnium oxide (HfO₂), a zinc oxide (ZnO), a magnesium oxide (MgO), a cesium oxide (Ce₂O₃), an indium oxide (In₂O₃), an indium tin oxide (ITO), barium titanate (BaTiO₃), potassium titanate (KTaO₃), (Ba, Sr)TiO₃, or any combination thereof.

According to at least one embodiment, the reflective layer is formed of titanium (Li), aluminum (Al), nickel (Ni), silver (Ag), chromium (Cr), platinum (Pt), molybdenum (Mo), copper (Cu), gold (Au), tungsten (W), iridium (Ir), or any combination thereof.

According to at least one embodiment, the insulating layer is formed of chromium-based oxide (CrO or CrO₂), a copper-based oxide (CuO), a manganese-based oxide (MnO₂), cobalt-based oxide (CoO), a sulfide (CoS₂, Co₃S₄), a nickel-based oxide (Ni₂O₃), or any combination thereof.

According to at least one embodiment, the reflective layer is formed through non-conductive vacuum metalizing (NCVM) to have a porous structure.

According to at least one embodiment, the reflective layer is formed through NCVM to have surface resistance equal to or less than 1 kΩ.

According to at least one embodiment, the reflective layer is formed through NCVM to have transmissivity equal to or greater than 5%.

Various objects, advantages and features of the invention will become apparent from the following description of embodiments with reference to the accompanying drawings.

### BRIEF DESCRIPTION OF DRAWINGS

These and other features, aspects, and advantages of the invention are better understood with regard to the following Detailed Description, appended Claims, and accompanying Figures. It is to be noted, however, that the Figures illustrate only various embodiments of the invention and are therefore not to be considered limiting of the invention's scope as it may include other effective embodiments as well.

FIG. 1 is a cross-sectional view illustrating a window substrate with a bezel layer formed thereon according to an embodiment of the invention.

FIG. 2 is a partially enlarged view of a portion ‘A’ in FIG. 1 according to an embodiment of the invention.

FIG. 3 is a partially enlarged cross-sectional view of a bezel layer according to another embodiment of the invention.

FIG. 4 is a cross-sectional view illustrating a window substrate with a bezel layer formed thereon according to another embodiment of the invention.

FIG. 5 is a cross-sectional view illustrating a touch sensor integrated with a window substrate according to another embodiment of the invention.

FIG. 6 is a cross-sectional view illustrating a touch sensor according to another embodiment of the invention.

### DETAILED DESCRIPTION

Advantages and features of the present invention and methods of accomplishing the same will be apparent by referring to embodiments described below in detail in connection with the accompanying drawings. However, the present invention is not limited to the embodiments disclosed below and may be implemented in various different forms. The embodiments are provided only for completing the disclosure of the present invention and for fully representing the scope of the present invention to those skilled in the art.

For simplicity and clarity of illustration, the drawing figures illustrate the general manner of construction, and descriptions and details of well-known features and techniques may he omitted to avoid unnecessarily obscuring the discussion of the described embodiments of the invention. Additionally, elements in the drawing figures are not necessarily drawn to scale. For example, the dimensions of some of the elements in the figures may be exaggerated relative to other elements to help improve understanding of embodiments of the present invention. Like reference numerals refer to like elements throughout the specification.

Hereinafter, various embodiments of the present invention will he described in detail with reference to the accompanying drawings.

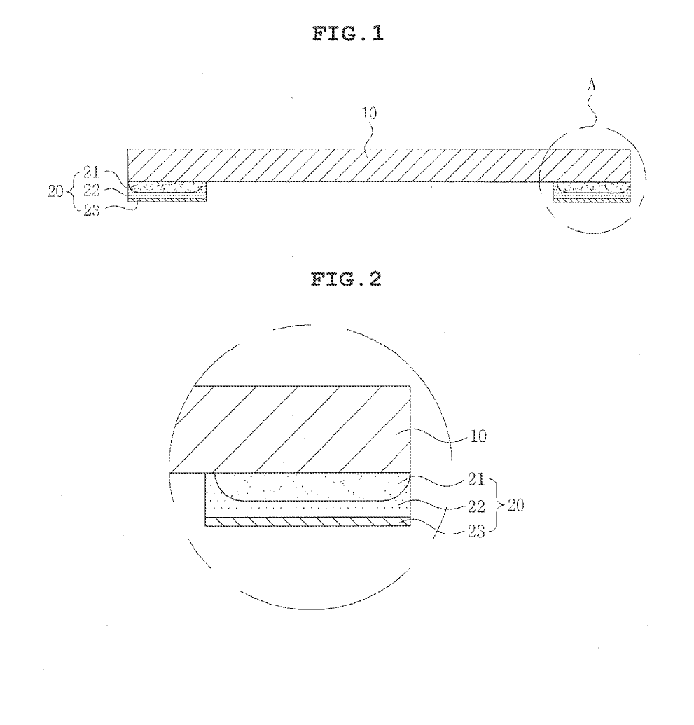

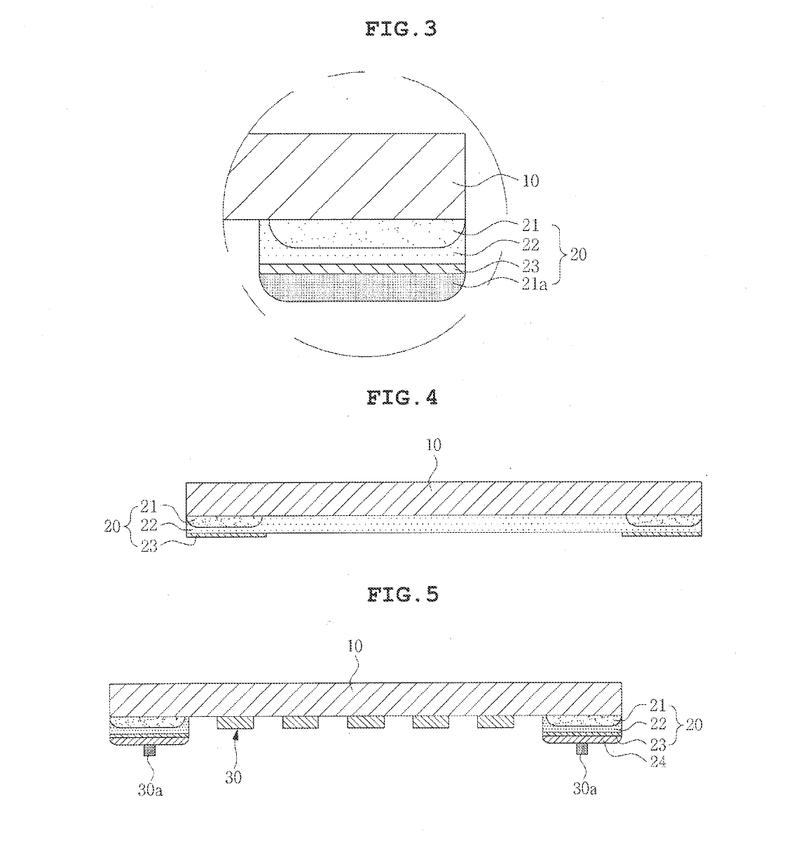

FIG. 1 is a cross-sectional view illustrating a window substrate 10 with a bezel layer 20 formed thereon according to an embodiment of the invention, FIG. 2 is a partially enlarged view of a portion ‘A’ in FIG. 1 according to an embodiment of the invention, and FIG. 3 is a partially enlarged cross-sectional view of a bezel layer according to another embodiment of the invention.

According to at least one embodiment, a touch sensor 1 includes the window substrate 10 and the bezel layer 20 formed on outer edges of one surface of the window substrate 10. According to at least one embodiment, the bezel layer 20 includes a printed layer 21 formed on the window substrate 10, a medium layer 22 formed on the printed layer 21 and having a refractive index lower than that of the printed layer 21, and a reflective layer 23 formed on the medium layer 22.

According to at least one embodiment, as illustrated in FIG. 3, the bezel layer 20 further includes a black printed layer 21a formed on the reflective layer 23. With the black printed layer 21a formed to correspond to the region in which the printed layer 21 is formed, a black band is formed on the edges of a visible region of a display region including the touch sensor to effectively enhance user recognition of the visible region of the display. The black printed layer 21a is formed of ga carbon-based material (e.g., graphene oxide, diamond line carbon (DLC)), a chromium-based oxide (CrO or CrO₂), a copper-based oxide (CuO), a manganese-based oxide (MnO₂), a cobalt-based oxide (CoO), a sulfides (CoS₂, Co₃S), a nickel-based oxide (Ni₂O₃), or any combination thereof.

Other components and operations will be described hereinbelow.

According to at least one embodiment, the window substrate 10 is formed on the outermost portion of the touch sensor 1 to serve to protect the touch sensor 1 from an external environment. For user visibility, the window substrate 10 is formed of a transparent material, but various embodiments of the invention are not limited thereto. For example, the window substrate 120 is made of a material having strength equal to or greater than a predetermined level, such as glass or tempered glass. In at least one embodiment of the invention, an electrode pattern 30 is directly formed together with the bezel layer 20 on the window substrate 10, whereby the touch sensor 1 is reduced in thickness and size and has enhanced touch sensitivity. However, besides the structure in which the electrode pattern 30 is directly formed on the window substrate 10, it would be obvious to a person skilled in the art that various other structures of the touch sensor 1 may be selectively applied. For example, the electrode pattern 30 may be formed on a separate base substrate 40 and the base substrate 40 may be coupled to the window substrate 10.

According to at least one embodiment, the bezel layer 20 is formed on outer edges of one surface of the window substrate 10. The bezel layer 20 is generally formed as a non-active region, such that a user's touch input is not recognized. Also, the bezel layer 20 serves to prevent an electrode wiring 30a for an electrical connection of the electrode pattern 30 formed on the touch sensor 1 from being visible or to decorate the exterior of various devices applied thereto, such as forming various logos on the outside thereof. In particular, unlike conventional bezel layers having a simple black color, the recent trend is towards implementation of various colors, causing a problem of a gradual increase in the thickness of the bezel layer 20. In consideration of the fact that the bezel layer 20 has a shielding function to prevent the electrode wiring 30a from being visible, it is required for the bezel layer 20 to effectively implement such a function although it has a color with a bright tone such as white or pink and has a small thickness.

According to at least one embodiment, as illustrated in FIG. 2, the bezel layer 20 includes the printed layer 21 formed on the window substrate 10, the medium layer 22 formed on the printed layer and having a refractive index lower than that of the printed layer 21, and the reflective layer 23 formed on the medium layer 22.

According to at least one embodiment, the printed layer 21 substantially represents a color of the bezel layer 20, and is formed by using various methods, such as screen printing, deposition, spin coating, as non-limiting examples, according to a selected material. In particular, in according with at least one embodiment, in order to implement the bezel layer 20 to have a white color, the bezel layer 20 is selectively formed of a titanium dioxide (TiO₂), an aluminum oxide (Al₂O₃), a silicon dioxide (SiO₂), a hafnium oxide (HfO₂), a zinc oxide (ZnO), a magnesium oxide (MgO), a cesium oxide (Ce₂O₃), an indium oxide (In₂O₃), an indium tin oxide (ITO), barium titanate (BaTiO₃), potassium titanate (KTaO₃). (Ba, Sr)TiO₃, or any combination thereof. However, the printed layer 21 according to an embodiment of the invention is not limited to a particular color and may be applied to various colors implemented through light reflection and such selection and application should be within a scope in which a person skilled in the art easily implements it or modifies a design thereof. Appropriately, the printed layer 21 is formed of a material having a refractive index equal to or greater than 1.4 in a wavelength range of visible light. This is to allow light to be effectively scattered in relation with the medium layer 22 and the reflective layer 23 to reveal a unique color of the printed layer 21 as described hereinafter. In this case, the refractive index in visible light is expressed as a function with respect to a wavelength, so a refractive index in a wavelength range of visible light is appropriately understood as a refractive index in a wavelength range from 550 nm to 600 nm.

According to at least one embodiment, the medium layer 22 is formed of a material having a refractive index lower than that of the printed layer 21. Here, a material of the medium layer 22 is not limited to a particular type of material, and any material, which has a refractive index making those of the printed layer 21 and the reflective layer 23 different significantly to allow a larger amount of light to be scattered from the printed layer 21 to effectively implement a color of the printed layer 21, is used. For example, the medium layer 22, according to at least one embodiment, is formed of an optical clear adhesive (OCA) through spin coating, or an air layer (not shown) formed by forming a gap between the printed layer 21 and the reflective layer 23 is implemented as the medium layer 22. Appropriately, the medium layer 22 has a refractive index smaller than that of the printed layer 21, and in particular, the medium layer has a refractive index ranging from 1 to 2.7 in a wavelength range of visible light. Also, in this case, since the refractive index in visible light is expressed as a function with respect to a wavelength, like the refractive index of the printed layer 21, a refractive index in a wavelength range of visible light is appropriately understood as a refractive index in a wavelength range from 550 nm to 600 nm.

Also, as illustrated ed in FIG. 4, in the case in which the OCA is formed, the OCA is coated on the entire surface of the window substrate 10, excluding the bezel layer 20 part, thereby further reducing a step with respect to the bezel layer 20. The step of the bezel layer 20 on the window substrate 10 is an important factor significantly affecting reliability of an electrical connection between the electrode pattern 30 and the electrode wiring 30a in the touch sensor 1 integrated with the window substrate 10 as described hereinafter. Details thereof will be described hereinbelow.

According to at least one embodiment, the reflective layer 23 is further formed on the medium layer 22 to effectively implement light scattering. The reflective layer 23 serves to more effectively reveal a color of the bezel layer 20 recognized by the user on the window substrate 10. Namely, incident light is reflected from the reflective layer 23 and internally scattered to make a color implemented on the printed layer 21 revealed readily. Accordingly, the bezel layer 20 for color implementation is reduced in thickness. According to at least one embodiment, the reflective layer 23 is made of a metal, but various embodiments of the invention are not necessarily limited thereto and a metal having reflectivity equal to or greater than 0.8 is applied. Since a numerical value of reflectivity of a metal is expressed as a function with respect to a wavelength, so it may be equal to or greater than 80% in a 800 nm wavelength range of visible light. Also, reflectivity is affected by gloss of a metal, and thus, reflectivity of a metal is also expressed as a numeral value of free electrons included in the metal as a cause of gloss of the metal. Namely, it is also expressed such that a metal used to form a reflective layer has specific resistance (ρ: Ωm) equal to or smaller than 10 at a temperature of 20° C.

According to at least one embodiment, the reflective layer 23 is formed of titanium (Ti), aluminum (Al), nickel (Ni), silver (Ag), chromium (Cr), platinum (Pt), molybdenum (Mo), copper (Cu), gold (Au), tungsten (W), iridium (Ir), or any combination thereof. Besides, obviously, various metals and nonmetal layers may be applied.

Also, the reflective layer 23 is formed of a non-conductive material. Namely, the reflective layer 23 is formed as a non-conductive thin film using tin (Sn) as a metal. The reflective layer 23 is formed of the conductive metal as described above, but the reflective layer 23 formed as a conductive metal layer interferes with antenna reception in a cellular phone, or the like, according to specifications and structures of an applied device. Thus, the non-conductive reflective layer 23, according to at least one embodiment, is applied according to an applied device to prevent the foregoing problem and effectively implement a color of the bezel layer of the touch sensor.

According to at least one embodiment, the non-conductive reflective layer 23 is formed of a metal layer by using a non-conductive vacuum metalizing (NCVM) for maintaining a reflection effect thereof. In the case of a film employing the NCVM, a radio frequency (RF) signal, such as Wi-Fi, is less interfered with, compared to a case of using any other metalizing method such as aluminum (Al). Namely, the non-conductive reflective layer 23 formed in this manner does not have conductivity, while having a reflecting effect, and thus, reliability related to antenna reception that may be generated according to an applied device is effectively secured.

In the case in which the reflective layer 23 formed as a metal layer is formed using the NCVM, the reflective layer 23 is formed to have a porous structure for insulation of the metal layers so as to have surface resistance equal to or greater than 1 kΩ, thus, advantageously not interfering with signal reception of an antenna installed in a device. Since the metal layer is used as is, the reflective layer 23 maintains transmissivity and reflecting effect, while assuming non-conductivity, and thus, it is more effective. According to at least one embodiment, the reflective layer 23 maintains transmissivity of at least 5%.

As illustrated in FIG. 5, in the touch sensor 1 according to at least one embodiment, the, since the electrode pattern 30 is directly formed on the window substrate 110, sensitivity of the touch sensor 1 is effectively increased. In the case of forming the electrode pattern 30 on the window substrate 10, the electrode pattern 30 having a monolayer structure is applied, and obviously, the touch sensor 1 is implemented by combining the electrode pattern 30 formed on the window substrate 10 and the electrode pattern 30 formed on the separate base substrate 40 to cross the foregoing electrode pattern 30.

For example, in the case of the electrode pattern 30 having a monolayer structure, when both crossing electrode patterns 30 are formed, an insulating pattern is formed in the intersection of the both electrode patterns 30 to insulate both electrode patterns 30 and electrically connect the respective electrode patterns 30. In order to implement the touch sensor 1 by forming the electrode patterns 30 on the window substrate 10, various other structures may be employed, including both a case in which the electrode patterns 30 are all formed on the window substrate 10 or a case in which a portion of the electrode patterns 30 is formed on the window substrate 10, and such a modification in design may be obvious to a person skilled in the art.

In an exemplary embodiment of the present invention, as illustrated in FIG. 5, the electrode pattern 30 having a uni-layer structure is formed on one surface of the window substrate 10. In this case, the electrode wiring 30a for electrical connection of the electrode pattern 30 is formed on the bezel layer 20. According to at least one embodiment, since the bezel layer 20 is implemented to have a reduced thickness, a step between the electrode wirings 30a connected in the electrode pattern 30 is significantly reduced, securing reliability of electrical connection between the electrode pattern 30 and the electrode wirings 30a.

According to at least one embodiment, the electrode pattern 30 serves to generate a signal by a touch input unit and recognize touch coordinates from a controller (not shown). The electrode pattern 30 is formed as a mesh pattern by using copper (Cu), aluminum (Al), gold (Au), silver (Ag), titanium (Ti), palladium (Pd), chromium (Cr), nickel (Ni), or any combination thereof. According to at least one embodiment, the electrode pattern 30 is formed of a metal oxide, such as metal silver formed by exposing and developing a silver salt emulsion layer, an indium tin oxide (ITO), as non-limiting examples, or a conductive polymer, such as PEDOP/PSS which has excellent flexibility and is simply coated, as non-limiting examples.

As illustrated in FIG. 5, in a case in which the reflective layer 23 is made of a metal, an insulating layer 24 is formed on the reflective layer 23 in order to prevent an electrical short-circuit with respect to the electrode wiring 30a. After the insulating layer 24 is stacked on the reflective layer 23, the electrode wiring 30a is formed on the insulating layer 24. A material of the insulating layer 24 is not particularly limited, but the insulating layer 24 having, a black color may be formed on the bezel layer 20 in order to prevent the electrode wiring 30a from being visible. For example, the insulating layer 24 is formed of a chromium-based oxide (CrO or CrO₂), a copper-based oxide (CuO), a manganese-based oxide (MnO₂), a cobalt-based oxide (CoO), a sulfide (CoS₂, Co₃S₄), a nickel-based oxide (Ni₂O₃), or any combination thereof. Also, the black printed layer 21a as described, above is also formed of an insulating material, so it may be formed to replace the insulating layer 24 within the range of a modification in design by a person skilled in the art.

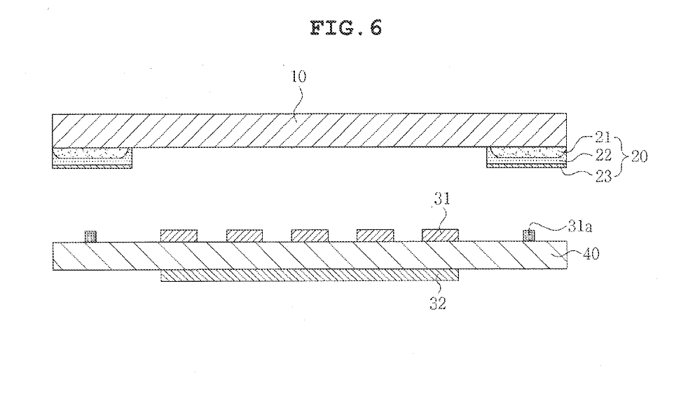

As illustrated in FIG. 6, in the touch sensor 1 according to another embodiment of the invention, a first electrode pattern 31 and a second electrode pattern 32 are formed on both surfaces of a separate base substrate 40, respectively, and the base substrate 40 is coupled to the window substrate 10 with the bezel layer 20 formed thereon.

As illustrated in FIG. 6, in the touch sensor 1 according to another embodiment of the present invention, after the window substrate 10, the bezel layer 20 formed on an outer circumference of one surface of the window substrate 10, the base substrate 40, the first electrode pattern 31 formed on one surface of the base substrate 40, and the second electrode pattern 32 formed on the other surface of the base substrate 40 to cross the first electrode pattern 31 are formed, the base substrate 40 and the window substrate 10 are combined. In this case, as illustrated in FIG. 5, the base substrate 40 and the window substrate 10 are combined, such that the first electrode pattern 31 and the window 10 oppose one another and the electrode wiring 31a is disposed in a position corresponding to the bezel layer 20 on the window substrate 10. Only the electrode wiring 31a electrically connected to the first electrode pattern 31 is illustrated in the drawing, but it may be obvious that an electrode wiring (not shown) for electrical connection to the second electrode pattern 32 is formed in a position corresponding to the bezel layer 20.

According to at least one embodiment, the base substrate 40 is made of any material as long as the material has strength equal to or greater than a predetermined level. The base substrate 40 is formed, for example, of polyethylene terephthalate (PET), polycarbonate (PC), polymethyl methacrylate (PMMA), polyethylene naphthalate (PEN), polyethersulfone (PES), cyclic olefin copolymer (COC), triacetylcellulose (TAC) film, a polyvinyl alcohol (PVA) film, a polyimide (PI) film, polystyrene (PS), biaxially oriented PS (BOPS) (containing K resin), or the like, but various embodiments of the invention are not necessarily limited thereto.

According to at least one embodiment, the first electrode pattern 31 and the second electrode pattern 32 are identical to the electrode pattern 30 as described above, so a detailed description thereof, which is repeated, will be omitted.

According to at least one embodiment of the invention, the bezel layer formed on the window substrate is reduced in thickness and various colors can be easily implemented.

Also, since the medium layer having a refractive index lower than that of the printed layer is formed on the printed layer and the reflective layer is formed on the medium layer, a color of the bezel layer is effectively implemented only with the thin printed layer.

In addition, in the window substrate-integrated touch sensor in which the electrode pattern is directly formed on the window substrate, in line with the reduction in the thickness of the bezel layer, higher electrical reliability is secured and operational performance of the touch sensor is enhanced.

Moreover, since the insulating layer is formed on the outermost layer of the bezel layer, reliability of shielding the bezel layer is enhanced.

Also, since the reflective layer is formed as a non-conductive thin film, reception interference of an antenna that may be generated according to types or specifications of applied devices is prevented in advance.

Also, since the reflective layer is formed as a non-conductive thin film, interference of radio frequency (RF) signals such as Wi-Fi according to applied devices is minimized.

In addition, since the reflective layer is formed as a metal layer through non-conductive vacuum metalizing (NCVM), conductivity may be lowered while transmissivity and reflectivity is effectively maintained.

Terms used herein are provided to explain embodiments, not limiting the present invention. Throughout this specification, the singular form includes the plural form unless the context clearly indicates otherwise. When terms “comprises” and/or “comprising” used herein do not preclude existence and addition of another component, step, operation and/or device, in addition to the above-mentioned component, step, operation and/or device.

Embodiments of the present invention may suitably comprise, consist or consist essentially of the elements disclosed and may be practiced in the absence of an element not disclosed. For example, it can be recognized by those skilled in the art that certain steps can he combined into a single step.

The terms and words used in the present specification and claims should not be interpreted as being limited to typical meanings or dictionary definitions, but should be interpreted as having meanings and concepts relevant to the technical scope of the present invention based on the rule according to which an inventor can appropriately define the concept of the term to describe the best method he or she knows for carrying out the invention.

The terms “first,” “second,” “third,” “fourth,” and the like in the description and in the claims, if any, are used for distinguishing between similar elements and not necessarily for describing a particular sequential or chronological order, it is to be understood that the terms so used are interchangeable under appropriate circumstances such that the embodiments of the invention described herein are, for example, capable of operation in sequences other than those illustrated or otherwise described herein. Similarly, if a method is described herein as comprising a series of steps, the order of such steps as presented herein is not necessarily the only order in which such steps may be performed, and certain of the stated steps may possibly be omitted and/or certain other steps not described herein may possibly be added to the method.

The singular forms “a,” “an” and “the” include plural referents, unless the context clearly dictates otherwise.

As used herein and in the appended claims, the words “comprise,” “has,” and “include” and all grammatical variations thereof are each intended to have an open, non-limiting meaning that does not exclude additional elements or steps.

As used herein, the terms “left,” “right,” “front,” “back,” “top,” “bottom,” “over,” “under,” and the like in the description and in the claims, if any, are used for descriptive purposes and not necessarily for describing permanent relative positions. It is to be understood that the terms so used are interchangeable under appropriate circumstances such that the embodiments of the invention described herein are, for example, capable of operation in other orientations than those illustrated or otherwise described herein. The term “coupled,” as used herein, is defined as directly or indirectly connected in an electrical or non-electrical manner. Objects described herein as being “adjacent to” each other may be in physical contact with each other, in close proximity to each other, or in the same general region or area as each other, as appropriate for the context in which the phrase is used. Occurrences of the phrase “according to an embodiment” herein do not necessarily all refer to the same embodiment.

Ranges may be expressed herein as from about one particular value, and/or to about another particular value. When such a range is expressed, it is to be understood that another embodiment is from the one particular value and/or to the other particular value, along with all combinations within said range.

Although the present invention has been described in detail, it should be understood that various changes, substitutions, and alterations can be made hereupon without departing from the principle and scope of the invention. Accordingly, the scope of the present invention should be determined by the following claims and their appropriate legal equivalents.

What is claimed is:

1. A touch sensor, comprising:
a window substrate; and
a bezel layer formed on outer edges of one surface of the window substrate,
wherein the bezel layer comprises:
a printed layer formed on the window substrate;
a medium layer formed on the printed layer and comprising a refractive index lower than that of the printed layer; and
a reflective layer formed on the medium layer.

2. The touch sensor as set forth in claim 1, further comprising:
a black printed layer formed on the reflective layer.

3. The touch sensor as set forth in claim 2, wherein the black printed layer is formed of a carbon-based material (graphene oxide, diamond line carbon (DLC)), a chromium-based oxide (CrO or CrO₂), a copper-based oxide (CuO), a manganese-based oxide (MnO₂), a cobalt-based oxide (CoO), a sulfide (CoS2, Co₃S₄), a nickel-based oxide (Ni₂O₃), or any combination thereof.

4. The touch sensor as set forth in claim 1, further comprising:
an electrode pattern formed within the bezel layer;
an insulating layer formed on the reflective layer of the bezel layer; and
an electrode wiring connected to one end of the electrode pattern and formed on the insulating layer to form an electrical connection.

5. The touch sensor as set forth in claim 1, wherein the printed layer comprises a material having a refractive index ranging from 1.3 to 2.7 in a wavelength range of visible light.

6. The touch sensor as set forth in claim 1, wherein the medium layer comprises a material having a refractive index ranging from 1 to 2.7 in a wavelength range of visible light.

7. The touch sensor as set forth in claim 6, wherein the medium layer is formed of an optical clear adhesive (OCA).

8. The touch sensor as set forth in claim 1, wherein the reflective layer is formed as a metal layer and reflectivity of the metal layer is equal to or greater than 0.8.

9. The touch sensor as set forth in claim 1, wherein the reflective layer is formed as a metal layer and specific resistance (ρ) of the metal layer is equal to or smaller than 10 at a temperature of 20° C.

10. The touch sensor as set forth in claim 1, wherein a thickness of the bezel layer in a stacking direction is equal to or smaller than 10 μm.

11. The touch sensor as set forth in claim 1, wherein the printed layer is formed of a titanium dioxide (TiO₂), an aluminum oxide (Al₂O₃), a silicon dioxide (SiO₂), a hafnium oxide (HfO₂), a zinc oxide (ZnO), a magnesium oxide (MgO), a cesium oxide (Ce₂O₃), an indium oxide (In₂O₃), an indium tin oxide (ITO), barium titanate (BaTiO₃), potassium titanate (KTaO₃), (Ba, Sr)TiO₃, or any combination thereof.

12. The touch sensor as set forth in claim 1, wherein the reflective layer is formed of titanium (Ti), aluminum (Al), nickel (Ni), silver (Ag), chromium (Cr), platinum (Pt), molybdenum (Mo), copper (Cu), gold (Au), tungsten (W), iridium (Ir), or any combination thereof.

13. The touch sensor as set forth in claim 4, wherein the insulating layer is formed of a chromium-based oxide (CrO or CrO₂), a copper-based oxide (CuO), a manganese-based oxide (MnO₂), a cobalt-based oxide (CoO), a sulfide (CoS₂, Co₃S₄), a nickel-based oxide (Ni₂O₃), or any combination thereof.

14. The touch sensor as set forth in claim 12, wherein the reflective layer is formed through non-conductive vacuum metalizing (NCVM) to have a porous structure.

15. The touch sensor as set forth in claim 12, wherein the reflective layer is formed through NCVM to have surface resistance equal to or less than 1 kΩ.

16. The touch sensor as set forth in claim 12, wherein the reflective layer is formed through NCVM to have transmissivity equal to or greater than 5%.
